(19) United States
(12) Patent Application Publication
(10) Pub. No.: US 2004/0223528 A1
(43) Pub. Date: Nov. 11, 2004

(54) Semiconductor light emitting devices including embedded curent injection layers

(75) Inventors: Donald E. Wortman, Rockville, MD (US); John D. Bruno, Bowie, MD (US)

Correspondence Address: Alan G. Towner, Pietragallo, Bosick & Gordon, One Oxford Centre, 38th Floor, 301 Grant Street, Pittsburgh, PA, 15219, US

(73) Assignee: Maxion Technologies, Inc., Hyattsville, MD

(21) Appl. No.: 10/841,860

(22) Filed: May 7, 2004

Related U.S. Application Data
(60) Provisional application No. 60/468,799, filed on May 8, 2003.

(51) Int. Cl. H01S 5/00

(52) U.S. Cl. 372/44; 372/46

(57) ABSTRACT

Electrically conductive, embedded current injection layers are provided in combination with cladding layers to provided improved current conduction to the active light-emitting regions of semiconductor light-emitting devices. The embedded electrical contact layers are used to inject current directly into the active region of semiconductor light-emitting devices. Free-carrier loss within the cladding layers is reduced, and power efficiency is improved by eliminating voltage drops associated with current transport through the cladding layers. Moreover, use of the embedded current injection layers eliminates the need to transport current through the cladding layers thereby allowing the use of a wider range of materials for the cladding layers. The present current injection layers may be embedded in various semiconductor light-emitting devices, i.e., both edge- and surface-emitting devices, such as semiconductor diode lasers, interband cascade lasers, light-emitting diodes and vertical cavity surface-emitting lasers.

### CROSS-REFERENCE TO RELATED APPLICATION

This application claims the benefit of U.S. Provisional Patent Application Serial No. 60/468,799 filed May 8, 2003, which is incorporated herein by reference.

### FIELD OF THE INVENTION

The present invention relates to semiconductor light-emitting devices, such as edge-emitting semiconductor diode lasers, surface-emitting semiconductor diode lasers, and edge- and surface-emitting light-emitting semiconducting diodes, and more particularly relates to the use of embedded current injection layers in such devices.

### BACKGROUND INFORMATION

Various types of optical semiconductor light-emitting devices are known. These include edge-emitting laser diodes, edge-emitting light-emitting diodes (LED's), surface-emitting laser diodes, including, e.g., vertical cavity surface-emitting lasers (VCSEL's), and surface-emitting LED's, including, e.g., resonant cavity LED's. For example, interband cascade lasers are disclosed in U.S. Pat. Nos. 5,588,015 and 6,404,791, which are incorporated herein by reference.

Such conventional devices typically include cladding layers directly adjacent to the active light-emitting region of the device which provide necessary optical characteristics for the device. For example, in edge-emitting interband cascade lasers, cladding layers are provided on either side of the active region. These cladding layers transport charge between the electrical contacts and the active region. They also provide refractive indices lower than that of the active region, thereby confining the optical energy emitted by the device to the active region. In LED's, a bottom layer in the form of a resonant reflector structure is sometimes provided next to the light-emitting active region in order to decrease the amount of light lost into the substrate region below the device structure. A lower cladding layer consisting of highly reflecting material can increase the amount of light emitted from the top of the device, thereby improving overall performance. In VCSEL's, cladding layers in the form of top and bottom mirror structures are provided on either side of the active light-emitting region. Such mirror layers function as reflectors sending light emitted from the active region back into the active region again. The combined function of the top and bottom VCSEL mirrors is to increase (through multiple reflections) the number of times light passes through the active region before leaving the top surface of the device.

Such conventional cladding layers may function as both optical waveguides and electrical current conductors, in which case there is a tradeoff between current conduction and optical properties. For example, if a cladding layer is optimized with respect to its optical characteristics, its ability to conduct electric current usually tends to decrease. Also, significant voltage drops and free-carrier optical loss can occur in the cladding layers when they are required to carry electrical current; cladding layers which are required to conduct electric current must be designed in a manner that generally compromises their optical characteristics.

The present invention has been developed in view of the foregoing.

### SUMMARY OF THE INVENTION

In accordance with the present invention, electrically conductive current injection layers are provided in combination with cladding layers to provide improved current conduction and optical confinement characteristics for the active light-emitting region of semiconductor light-emitting devices. Embedded electrical contact layer(s) are used to inject current directly into the active region of semiconductor light-emitting devices. Free-carrier optical loss within the cladding layers is reduced or eliminated since the presence of the embedded contact layers eliminates the need for the cladding layers to conduct electrical current. As a consequence, the cladding layers are not required to be grown with intentional impurities that provide for the current carrying capability (and also produce optical losses). Furthermore, the power efficiency of the device is improved by eliminating voltage drops associated with current transport through the cladding layers. The current injection layers may be embedded in various semiconductor light-emitting devices, such as edge-emitting diode lasers, edge-emitting LED's, vertical cavity surface-emitting lasers (VCSEL's), surface-emitting diodes, and the like. For example, the incorporation of current injection layer(s) in interband cascade laser designs allows the flexibility to use cladding layers with much improved optical properties.

An aspect of the present invention is to provide a semiconductor light-emitting device comprising an active light-emitting region, a first cladding layer, and a first current injection layer between the active light-emitting region and the first cladding layer.

Another aspect of the present invention is to provide a method of making a semiconductor light-emitting device. The method includes the steps of depositing a first cladding layer, depositing a first current injection layer over the first cladding layer, and depositing an active light-emitting region over the first current injection layer.

A further aspect of the present invention is to provide a method of making a semiconductor light-emitting device which includes the steps of depositing an active light-emitting region, depositing a current injection layer over the active light-emitting region, and depositing a cladding layer over the current injection layer.

These and other aspects of the present invention will be more apparent from the following description.

### BRIEF DESCRIPTION OF THE DRAWINGS

FIG. 1 is a partially schematic cross sectional view of an edge-emitting diode laser or LED including current injection layers in accordance with an embodiment of the present invention.

FIG. 2 is a partially schematic cross sectional view of a surface-emitting light-emitting diode device including current injection layers in accordance with a further embodiment of the present invention.

FIG. 3 is a partially schematic cross sectional view of a vertical cavity surface-emitting laser (VCSEL) including current injection layers in accordance with another embodiment of the present invention.

FIG. 4 schematically illustrates an interband cascade laser structure used to test various bottom current injection layers of the present invention.

### DETAILED DESCRIPTION

The present invention provides semiconductor light-emitting devices, such as semiconductor diode edge-emitting lasers, edge-emitting light-emitting diodes, vertical cavity surface-emitting laser, and surface-emitting light-emitting diodes which include at least one embedded current injection layer. The current injection layer may be embedded between an active light-emitting region of the device and a cladding layer.

As used herein, the terms “active light-emitting region” and “active region” mean the region of the semiconductor light-emitting device in which light is generated for radiation from the device. The light may be coherent or noncoherent and may comprise a single wavelength or multiple wavelengths within any desired range, e.g., visible, near infrared, mid infrared, etc.

The term “current injection layer” means a layer of material or materials which conduct electrical current to or from the active region of a semiconductor light-emitting device. At least a portion of the current injection layer may be oriented in a plane substantially parallel with the plane of the active region. The current injection layer may be partially or entirely coextensive with the adjacent active region layer.

As used herein, the term “cladding layer” means any type of cladding, reflector or mirror layer located outside of the active region of the light-emitting device which provides the desired optical performance for the device, such as confining, reflecting or guiding the generated light in a desired direction. The cladding layer may be partially or entirely coextensive with the current injection layer.

In one embodiment, a bottom current injection layer is provided between a bottom cladding layer and the active light-emitting region of the device. In another embodiment, a top current injection layer is provided between the active light-emitting region and a top cladding layer of the device. In a further embodiment, the device includes both a bottom current injection layer and a top current injection layer, with the active region therebetween. The current injection layer(s) may be used to supply electric current substantially parallel with the plane of the active region, and to inject carriers substantially perpendicular to the plane of the active region of the device. This arrangement reduces free-carrier losses by eliminating the need to dope the cladding layer with impurities (which provide for electrical conductivity); the current injection layers are used to carry the current instead of the cladding layers. The necessity of conducting current through the cladding layers is thus avoided. In addition, the present arrangement allows more options for topside cladding materials, including undoped semiconductor materials, Si₃N₄, SiO₂, air and the like.

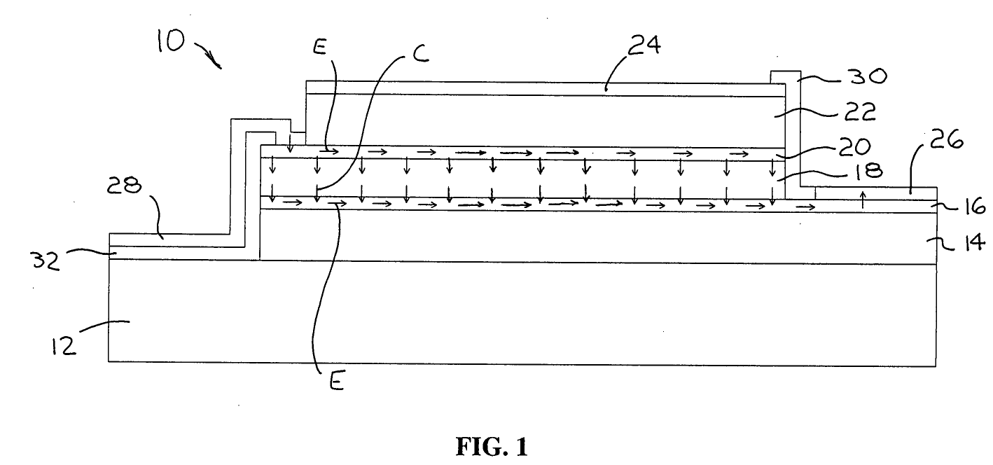

FIG. 1 illustrates a semiconductor light-emitting device in the form of an edge-emitting diode laser or LED 10 in accordance with an embodiment of the present invention. The device 10 includes a substrate 12 made of GaSb or any other suitable material. A bottom cladding layer 14, which may be undoped, is deposited on the substrate 12. A bottom current injection layer 16 is deposited over the bottom cladding layer 14. The device 10 includes an active light-emitting region 18 deposited on the bottom current injection layer 16. For example, the active region 18 may comprise an interband cascade structure, e.g., as described in U.S. Pat. Nos. 5,588,015 and 6,404,791. A top current injection layer 20 covers the active region 18, and a top cladding layer 22 is deposited on the top current injection layer 20. The top cladding layer 22 may be undoped. In the embodiment shown in FIG. 1, the layers 14, 16, 18, 20 and 22 are substantially coextensive with respect to each other. A cap layer 24 is deposited over the top cladding layer 22. The cap layer 24 may comprise any suitable material such as undoped GaSb.

As shown in FIG. 1, a bottom contact metal layer 26 such as Au, Ti and Au, or the like is deposited over a portion of the bottom current injection layer 16. A top contact metal layer 28 contacts the top current injection layer 20. An insulating material 30 such as SiO₂, Si₃N₄ or the like separates the active region 18 from the bottom contact metal layer 26. Another insulating layer 32 made of SiO₂, Si₃N₄ or the like separates the top contact metal layer 28 from the active region 18, bottom current injection layer 16 and bottom cladding layer 14. Standard photolithography may be used to make ohmic electrical contact between the metal signal leads 26 and 28 and the current injection layers 16 and 20.

The cladding layers 14 and 22 act to optically confine light within the active region 18 of the device to thereby form a waveguide for the light. The current injection layers 16 and 20 transport current E to and from the active region 18 of the device, preferably in a direction parallel with the plane of the active region 18, in order to provide substantially uniform injection of current into the active region in a direction perpendicular to the plane of the active region. The current E is thus supplied laterally through the current injection layers 16 and 20 and carriers C are injected vertically into the active region 18 from the current injection layers 16 and 20.

The thickness and doping level of the current injection layers 16 and 20 may be optimized in order to minimize free-carrier losses within the current injection layers 16 and 20, while maintaining a sufficiently low resistance to minimize the lateral voltage drop along the, layers and maintaining suitable optical characteristics. More specifically, to maintain uniform current injection into the active region 18 along the entire width of the mesa, the current injection layer lateral resistance should be small relative to the vertical resistance of the active region 18. This is particularly applicable to interband cascade light emitters where the forward bias resistance (vertical resistance) can be adjusted by changing the number of cascade stages. Consequently, it is possible to reduce the necessary doping in the current injection layers (reducing free-carrier losses) by increasing the number of cascade stages.

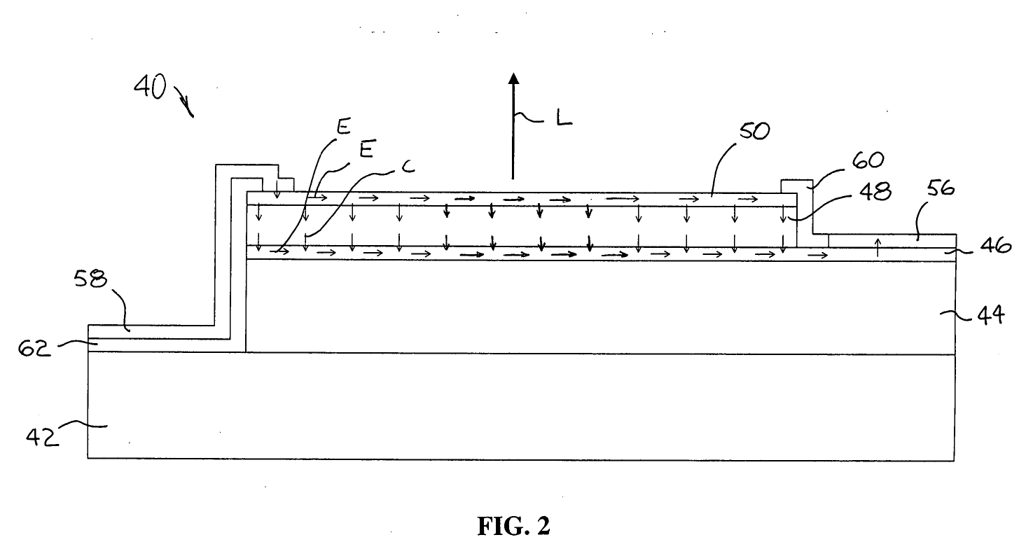

FIG. 2 illustrates a semiconductor light-emitting device in the form of a surface-emitting light-emitting diode (LED) 40 in accordance with another embodiment of the present invention. The surface-emitting light-emitting diode 40 includes a substrate 42 made of GaSb or other suitable material. A cladding layer 44 in the form of a resonant reflector structure can be deposited on the substrate 42 as depicted, although this is not necessary. The resonant reflector structure 44 may be undoped and may comprise alternating layers of materials with high and low refractive indices, for example, alternating layers of GaSb and AlAsSb can be used. A bottom current injection layer 46 is deposited on the cladding layer 44. The light-emitting diode 40 includes an active region 48 deposited on the bottom current injection layer 46. The active region 48 may comprise of multiple layers of InAs, AlSb, GaSb, GaInSb, AlInSb, and similar alloys suitably sized to produce the desired electronic structure. A top current injection layer 50 is deposited on the active region 48.

As shown in FIG. 2, a bottom contact metal layer 56 made of Au, Ti and Au, or the like is deposited over a portion of the bottom current injection layer 46. A top contact metal layer 58 contacts the top current injection layer 50. Top contact metal layer 58 may be made of any suitable metal such as Au, Ti and Au or the like. An insulating layer 60 made of SiO₂, Si₃N₄ or the like is provided between the active region 48 and the bottom contact metal layer 56. Another insulating layer 62 made of SiO₂, Si₃N₄ or the like separates the top contact metal layer 58 from the active region 48, bottom current injection layer 46 and bottom resonant reflector structure 44.

The LED 40 with the bottom reflective cladding layer 44 operates as follows. Current directed through the active region 48 generates light which is emitted in all directions. The intensity of the emitted light is directly proportional to the amount of current injected. Current-generated light which propagates down towards the substrate 42 is reflected by the highly reflective bottom cladding layer 44. As a consequence of the bottom reflective cladding layer 44, most of the light emitted along a vertical axis L, is emitted out through the top of the LED structure.

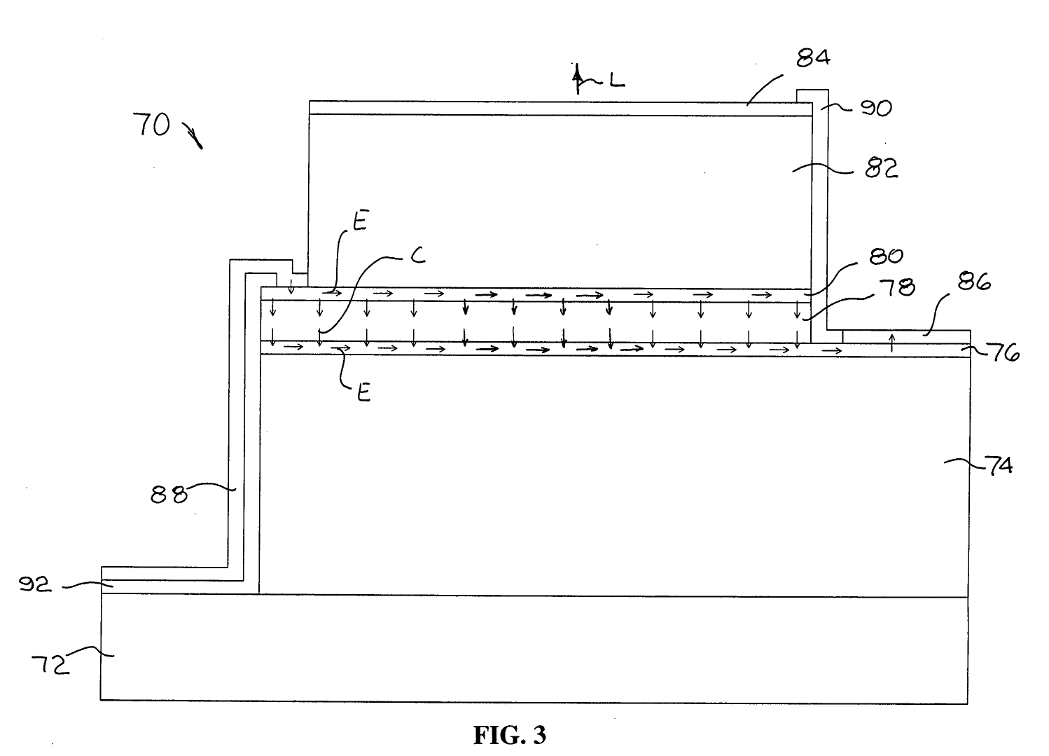

FIG. 3 illustrates a semiconductor light-emitting device in the form of a vertical cavity surface emitting laser (VCSEL) 70 in accordance with a further embodiment of the present invention. The VCSEL 70 includes a substrate 72 made of GaSb or any other suitable material. A bottom highly-reflecting cladding layer 74, which may be preferably undoped, is deposited on the substrate 72. A bottom current injection layer 76 is deposited over the bottom cladding layer 74. The VCSEL 70 includes an active light-emitting region 78 deposited on the bottom current injection layer 76. A top current injection layer 80 covers the active region 78, and a top highly-reflecting cladding layer 82 is deposited on the top current injection layer 80. The top cladding layer 82 may be preferably undoped. A cap layer 84 is deposited over the top cladding layer 82. The cap layer 84 may comprise any suitable material such as undoped GaSb.

As shown in FIG. 3, a bottom contact metal layer 86 such as Au, or Ti and Au or the like is deposited over a portion of the bottom current injection layer 76. A top contact metal layer 88 contacts the top current injection layer 80. An insulating material 90 such as SiO₂, S ₃N₄ or the like separates the active region 78 from the bottom contact metal layer 86. Another insulating layer 92 made of SiO₂, Si₃N₄ or the like separates the top contact metal layer 88 from the active region 78, bottom current injection layer 76, and bottom cladding layer 74. The vertical cavity surface emitting laser 70 emits laser light L from the active region 78 through the top current injection layer 80, top mirror structure 82 and cap layer 84.

The VCSEL 70 operates as follows. Current injected through the active region 78 results in the emission of radiation in all directions, as occurs in the LED structure previously described. Again, the intensity of this radiation is directly proportional to the amount of current injected through the active region. The emitted radiation which is incident vertically on the top 82 or bottom 74 highly-reflecting cladding layers is reflected back into the active region light-emitting region 78. This “vertically-moving” radiation or “cavity radiation” passes back through the active region multiple times (following multiple reflections) and can thereby stimulate the emission of additional cavity radiation. This causes positive feedback—the more light that is reflected back into the active region, the more light is stimulated into the cavity mode. The buildup of light in the cavity mode increases until the net round-trip amplification of light matches the round-trip losses caused by transmission through the mirror structures 82 and 74 and other scattering and absorption losses in the material. When this condition is met, the device begins to lase.

In accordance with the present invention, the current injection layers preferably have in-plane lattice constants which substantially match the in-plane lattice contants of the adjacent cladding layers, e.g., the lattice constants vary by less than 0.5 percent, preferably less than 0.3 percent. Furthermore, the current injection layers preferably have in-plane lattice constants which substantially match the in-plane lattice constant of the adjacent active light-emitting region of the device. For example, the device may include a bottom current injection layer having an in-plane lattice constant which substantially matches the in-plane lattice constant of the bottom cladding layer and the in-plane lattice constant of the active light-emitting region.

The current injection layers of the present invention typically have a thickness of less than about 1 micron. For example, each current injection layer may have a thickness of from about 0.05 or 0.1 micron to about 0.5 micron.

In accordance with an embodiment of the present invention, the cladding layers are undoped, while the current injection layers are doped. The current injection layers may comprise any suitable material, for example, at least one material selected from Ga and In, and at least one material selected from As, P and Sb. For example, the current injection layers may comprise GaSb, GaAs, InP, GaInAs, InAs, GaSb/InAs, GaInSb, GaSb/GaAs, InAs/InSb and/or GaInSb/GaInAs. As a particular example, the current injection layer may comprise GaSb. Suitable dopants for the current injection layers include Be and/or Zn for p-type doping, and Te, Se and/or Si for n-type doping. One design for the current injection layer is a highly p-doped GaSb layer placed between the cladding and active regions.

The cladding layers may comprise any suitable material, such as at least one material selected from Al, Ga and In, and at least one material selected from As, P and Sb. Furthermore, the top cladding layers may comprise SiO₂, Si₃N₄, air or other material with suitable optical properties.

Some of the present semiconductor light-emitting devices operate in the mid-IR wavelength range (3 to 5 μm) and may be extended to the long wavelength range (out to about 12 μm). For lasers operating in this range, relatively thick cladding layers, with low refractive index compared to the active region, are used to confine an optical mode within the active region.

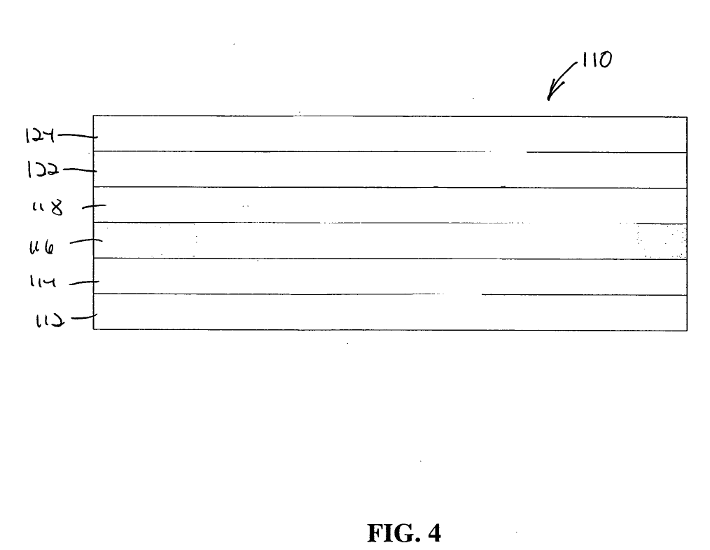

FIG. 4 schematically illustrates an interband cascade edge-emitting laser structure used to test various bottom current injection layers in the following examples. The interband cascade laser structure 110 includes a p-GaSb substrate 112, an undoped AlAsSb cladding layer 114 having a thickness of 2 microns, a bottom current injection layer 116 having varying thicknesses and doping levels, an active region 118 comprising 18 cascaded stages of a multilayer structure consisting of layers of InAs, AlSb, AlInSb, GaInSb and GaSb of varying layer thicknesses which produces the desired electronic structure, an n-doped InAs/AlSb top cladding layer 122 having a thickness of 1.5 micron, and an n-InAs top contact layer 124 having a thickness of 0.35 micron. In each of Examples 1-5 below, an interband cascade laser structure as shown in FIG. 4 was fabricated and tested. The overall structure of the IC laser was maintained, except the thickness and doping level of the GaSb lateral current injection layer was changed.

### EXAMPLE 1

An IC laser containing a bottom contact lateral current injection layer of the present invention and a standard doped top-side cladding layer was fabricated as shown in FIG. 4. The lateral injection layer in this sample is a 0.4 μm thick GaSb layer p-doped with Be at 8×10¹⁸ cm⁻³. Current is injected through the top-side contact, passes through the top-side cladding and active layer, then exits the structure through the p-GaSb lateral current injection layer. In this sample the lateral current injection layer worked well for effective current injection into the active region. Devices made from this material lased.

### EXAMPLE 2

Example 1 was repeated, except the lateral injection layer Be doping was decreased to 4×10¹⁸ cm⁻³. The operating characteristics of lasers fabricated from this material showed that this version of the lateral current injection layer worked well for current injection. Devices made from this material lased.

### EXAMPLE 3

Example 1 was repeated, except the lateral injection layer thickness was decreased to 0.3 μm. Once again, the operating characteristics of lasers fabricated from this material showed that this version of the lateral current injection layer worked well for current injection. Overall, lasers fabricated from this material worked well.

### EXAMPLE 4

Example 3 was repeated, except the AlAsSb ternary cladding material was replaced with an AlSb/AlAs cladding superlattice. The lateral injection again worked well, and the overall laser performance was good.

### EXAMPLE 5

Example 1 was repeated, except the lateral current injection layer thickness was decreased to 0.225 μm and the Be doping was increased to 1.3×10¹⁹ cm⁻³. The lateral injection again worked well, and the overall laser performance was good.

Examples 1-5 describe several variations of the p-doped GaSb current injection layer with the thickness ranging from 0.225 to 0.4 μm and the Be doping level ranging from 4×10¹⁸ to 1.3×10¹⁹ cm⁻³. Alternatively, other materials such as Zn could be used as an alternative p-type dopant. The layer could be doped n-type as well, using Te or Se as the n-type dopant.

An advantage of the lateral current injection arrangement of the present invention is the reduction of fi-ee-carrier optical absorption of light within the cladding layers since the cladding layers are now undoped. Without lateral injection the cladding layers must be doped to conduct carriers to the active region. The potential for reduced free-carrier losses in accordance with the present invention can lead to a lower net internal loss, which in turn allows a lower threshold current for lasing to occur. Furthermore, unwanted voltage drops caused by passing current through doped cladding layers having a finite resistance can be eliminated. This improves the overall power efficiency of the devices. In addition, use of the embedded current injection layers eliminates the need to transport current through the cladding layers thereby allowing the use of a wider range of materials for the cladding layers.

Whereas particular embodiments of this invention have been described above for purposes of illustration, it will be evident to those skilled in the art that numerous variations of the details of the present invention may be made without departing from the invention as defined in the appended claims.

1. A semiconductor light-emitting device comprising:
an active light-emitting region;
a first cladding layer; and
a first current injection layer between the active light-emitting region and the first cladding layer.

2. The semiconductor light-emitting device of claim 1, wherein the first current injection layer and the active light-emitting region are structured and arranged to supply electric current substantially parallel with a plane of the first current injection layer and to inject carriers substantially perpendicular to a plane of the active light-emitting region.

3. The semiconductor light-emitting device of claim 1, wherein the first current injection layer and the active light-emitting region are substantially coextensive.

4. The semiconductor light-emitting device of claim 1, wherein the first current injection layer and the first cladding layer are substantially coextensive.

5. The semiconductor light-emitting device of claim 1, wherein the first current injection layer has an in-plane lattice constant which is substantially matched with an in-plane lattice constant of the first cladding layer.

6. The semiconductor light-emitting device of claim 1, wherein the first current injection layer has an in-plane lattice constant which is substantially matched with an in-plane lattice constant of the active light-emitting region.

7. The semiconductor light-emitting device of claim 1, wherein the first current injection layer has an in-plane lattice constant which is substantially matched with an in-plane lattice constant of the first cladding layer and an in-plane lattice constant of the active light-emitting region.

8. The semiconductor light-emitting device of claim 1, wherein the first current injection layer has a thickness of less than about 1 micron.

9. The semiconductor light-emitting device of claim 1, wherein the first current injection layer has a thickness of from about 0.1 to about 0.5 micron.

10. The semiconductor light-emitting device of claim 1, wherein the first cladding layer is undoped.

11. The semiconductor light-emitting device of claim 1, wherein the first current injection layer is doped.

12. The semiconductor light-emitting device of claim 1, wherein the first cladding layer is undoped and the first current injection layer is doped.

13. The semiconductor light-emitting device of claim 1, wherein the first current injection layer comprises at least one material selected from Ga and In, and at least one material selected from As, P and Sb.

14. The semiconductor light-emitting device of claim 13, wherein the first current injection layer comprises GaSb, GaAs, InP, GaInAs, InAs, GaSb/InAs, GaInSb, GaSb/GaAs, InAs/InSb and/or GaInSb/GaInAs.

15. The semiconductor light-emitting device of claim 13, wherein the first current injection layer comprises GaSb.

16. The semiconductor light-emitting device of claim 13, wherein the first current injection layer further comprises a dopant.

17. The semiconductor light-emitting device of claim 16, wherein the dopant comprises Be and/or Zn.

18. The semiconductor light-emitting device of claim 16, wherein the dopant comprises Te, Se and/or Si.

19. The semiconductor light-emitting device of claim 1, wherein the first cladding layer comprises at least one material selected from Al, Ga and In, and at least one material selected from As, P and Sb.

20. The semiconductor light-emitting device of claim 19, wherein the first cladding layer is undoped.

21. The semiconductor light-emitting device of claim 1, further comprising a second current injection layer adjacent to an opposite side of the active light-emitting region from the first current injection layer.

22. The semiconductor light-emitting device of claim 21, wherein the second current injection layer is doped.

23. The semiconductor light-emitting device of claim 21, further comprising a second cladding layer adjacent to the second current injection layer on an opposite side from the active light-emitting region.

24. The semiconductor light-emitting device of claim 23, wherein the second cladding layer is undoped.

25. The semiconductor light-emitting device of claim 21, further comprising a first metal contact connected to the first current injection layer, and a second metal contact connected to the second current injection layer.

26. The semiconductor light-emitting device of claim 1, wherein the device comprises an edge-emitting diode laser.

27. The semiconductor light-emitting device of claim 1, wherein the device comprises an edge-emitting light-emitting diode.

28. The semiconductor light-emitting device of claim 1, wherein the active light-emitting region is an interband cascade active region.

29. The semiconductor light-emitting device of claim 1, wherein the device comprises a surface-emitting diode laser.

30. The semiconductor light-emitting device of claim 1, wherein the device comprises a surface-emitting light-emitting diode.

31. The semiconductor light-emitting device of claim 1, wherein the device comprises a vertical cavity surface emitting laser.

32. A method of making a semiconductor light-emitting device, the method comprising:
depositing a first cladding layer;
depositing a first current injection layer over the first cladding layer; and
depositing an active light-emitting region over the first current injection layer.

33. The method of claim 32, wherein the first current injection layer is substantially coextensive with the active light-emitting region.

34. The method of claim 32, wherein the first current injection layer is substantially coextensive with the first cladding layer.

35. The method of claim 32, further comprising depositing a second current injection layer over the active light-emitting region.

36. The method of claim 35, further comprising depositing a second cladding layer over the second current injection layer.

37. A method of making a semiconductor light-emitting device, the method comprising:
depositing an active light-emitting region;
depositing a top current injection layer over the active light-emitting region; and
depositing a top cladding layer over the top current injection layer.

38. The method of claim 37, wherein the top current injection layer is substantially coextensive with the active light-emitting region.

39. The method of claim 37, wherein the top current injection layer is substantially coextensive with the top cladding layer.

40. The method of claim 37, wherein the active light-emitting region is deposited over a bottom current injection layer.

41. The method of claim 40, wherein the bottom current injection layer is deposited over a bottom cladding layer.
